(19) United States
(12) Patent Application Publication
(10) Pub. No.: US 2014/0145553 A1
(43) Pub. Date: May 29, 2014

(54) VIBRATION ELEMENT AND ELECTRONIC DEVICE

(71) Applicant: Seiko Epson Corporation, Tokyo (JP)

(72) Inventors: Ryuji Kihara, Matsumoto (JP); Aritsugu Yajima, Matsumoto (JP)

(73) Assignee: Seiko Epson Corporation, Tokyo (JP)

(21) Appl. No.: 14/083,984

(22) Filed: Nov. 19, 2013

(30) Foreign Application Priority Data
Nov. 28, 2012 (JP) 2012-259442

(51) Int. Cl. B81B 3/00

(52) U.S. Cl. CPC B81B 3/0097
USPC 310/300

(57) ABSTRACT

A MEMS vibration element 100 includes a substrate 1, fixing parts 23 provided on a principal surface of the substrate 1, supporting parts (supporting beams 22 and connection beams 21) extending from the fixing parts 23, and an upper electrode (a vibration body) supported by the supporting parts, isolated from the substrate 1. The upper electrode 20 includes cut sections 30 each extending from the peripheral portion of the upper electrode 20 toward the central portion of the upper electrode 20, the cut sections 30 exposing side surfaces 31 of the upper electrode 20. The upper electrode 20 includes joining parts provided at the side surfaces 31 oriented in a direction from the peripheral portion toward the central portion of the upper electrode 20, and the joining parts are connected to the supporting parts 22.

### BACKGROUND

1. Technical Field

The present invention relates to vibration elements and electronic devices.

2. Related Art

Electromechanical system structures (such as, for example, vibration elements, filters, sensors, motors, etc.) equipped with a mechanically movable structure, which is called a MEMS (Micro Electro Mechanical System) fabricated using the micro-processing technology, are publicly known. Compared with vibration elements and resonators that use crystal and dielectric substance that have been primarily used so far, the use of MEMS vibration elements, among the electromechanical system structures, has become more active because MEMS vibration elements can be readily manufactured with semiconductor circuits built therein, and are more advantageous for achieving further miniaturization and higher performance.

As representative examples of known MEMS vibration elements, the comb type vibration element that vibrates in the direction parallel with the substrate surface, and the beam type vibration element that vibrates in the direction of thickness of the substrate are known. The beam type vibration element is a vibration element composed of a lower electrode (fixed electrode) formed on the substrate and an upper electrode (movable electrode) arranged with a gap provided above the lower electrode. As the beam type vibration element, a cantilever beam type (clamped-free beam), a double-supported beam type (clamped-clamped beam), and a both-end support-free beam type (free-free beam) are known depending on how the upper electrode is supported.

Because the vibrating upper electrode is supported by support members at portions at nodes of vibration, the MEMS vibration element of free-free type beam has high vibration efficiency as vibration leakage to the substrate is little. U.S. Pat. No. 6,930,569B2 (Patent Document 1) proposes a technology that improves the vibration characteristic by setting the length of the support members at an appropriate length to the frequency of the vibration.

However, there are problems in that the prior art technology described above, including the MEMS vibration element described in Patent Document 1, cannot sufficiently meet the needs for further miniaturization, reduction in thickness, power saving, or higher frequency. Specifically, to meet the requirements for miniaturization, reduction in thickness, power saving, and higher frequency, a MEMS vibration element of free-free beam type may be used, and it may be effective to reduce the stiffness (rigidity) of the upper electrode and the supporting parts, and to reduce the gap between the electrodes. As a result, however, sticking of the upper electrode in the manufacturing process is induced, such that sufficient manufacturing yield could not be achieved. Sticking is a phenomenon in which minute structures adhere to the substrate and other structures when the sacrificial layer is etched and removed for forming the MEMS structure. In other words, the problem that the upper electrode sticks to the lower electrode has become apparent while attempting to meet the above-described needs in the prior art manufacturing process.

### SUMMARY OF THE INVENTION

The invention has been made to solve at least a part of the problems described above, and may be realized as one of application examples and embodiments to be described below.

### Application Example 1

A vibration element in accordance with an application example of the invention includes a substrate, a fixing part provided on a principal surface of the substrate, a supporting part extending from the fixing part, and a vibration body supported by the supporting part, isolated from the substrate. The vibration body includes a cut section extending from the peripheral portion of the vibration body toward the central portion of the vibration body, and a joining part provided at aside surface portion exposed by the cut section, and orienting in a direction from the peripheral portion toward the central portion. The joining part is connected to the supporting part.

According to an aspect of the present application example, the vibration body has the joining part provided at a side surface portion of the vibration body orienting in a direction from the peripheral portion toward the central portion of the vibration body, exposed by the cut section orienting in a direction from the peripheral portion toward the central portion of the vibration body, and the joining part is connected with the supporting part. In other words, as the supporting part connects to the joining part located on the inner side of (more specifically, on the radially inner side of) the peripheral portion of the vibration body and supports the vibration body, a vibration element that vibrates with the peripheral portion and the central portion (i.e., the portion on the inner side of the joining part) of the vibration body as anti-nodes can be composed.

In the case of the prior art vibration element of free-free beam type, for example, the supporting parts are connected to nodes of vibration located on the side surfaces of the vibrating plate, such that the number of supporting parts cannot be increased greater than the number of nodes of vibration on the side surfaces. Moreover, the supporting parts need to be extended in a direction away from the side surfaces of the vibration plate, such that the area occupied by the vibrating element including the supporting parts unavoidably becomes greater than that of the vibrating plate.

In contrast, according to the composition of the application example, the vibration body is provided with the cut section extending from the peripheral portion toward the node of vibration located on the inner side of the vibration body, and the joining part that connects with the supporting part is formed on the side surface exposed by the cut section, such that, by providing the necessary number of cut sections, the number of supporting parts may be increased without any limitation. As a result, the rigidity for supporting the vibration body increases. Accordingly, for example, in the manufacturing process of forming the vibration body that is isolated over the primary surface of the substrate, the sticking phenomenon in which the vibration body adheres to the primary surface of the substrate would be difficult to occur, even when the surface tension of etching liquid and cleaning liquid act between them. As a result, reduction of yield due to sticking can be suppressed.

Furthermore, the supporting part and the fixing part are provided in empty area created by the cut section, such that the vibrating element can be composed without extending the supporting part outside the vibration body, or the extension length of the supporting part can be made shorter, which can further reduce the size of the vibrating element.

### Application Example 2

In the vibration element according to the application example described above, the vibration body may preferably be a circular plate body having the cut section.

According to the present application example, by forming the vibration plate from a circular plate body having the cut section, a vibration element that vibrates with the peripheral portion and the central portion of the vibration body as anti-nodes can be composed. As the vibration body is formed in a circular shape, the positions of vibration nodes and vibration characteristics can be readily designed.

### Application Example 3

In the vibration element according to the application example described above, the vibration body may preferably be provided with a plurality of the cut sections.

According to the present application example, due to the structure in which the vibration body is provided with plural cut sections, and is supported by plural supporting parts connected to plural joining parts exposed by the plural cut sections, the rigidity for supporting the vibration body increases. Any necessary number of cut sections can be provided, and joining parts to be connected to the supporting parts can be exposed, such that the number of supporting parts can be increased without any limitation. As a result, the rigidity for supporting the vibration body increases. Accordingly, for example, in the manufacturing process of forming the vibration body that is isolated over the primary surface of the substrate, the sticking phenomenon in which the vibration body adheres to the primary surface of the substrate would be difficult to occur, even when the surface tension of etching liquid and cleaning liquid act between them. As a result, reduction of the yield due to sticking can be suppressed.

### Application Example 4

In the vibration element according to the application example described above, the fixing part may be provided in an area that overlaps the cut section, as the substrate is viewed in a plan view.

According to the present application example, as the fixing part is provided in an area that overlaps the cut section, in other words, an empty area created by the cut section, the vibration element can be structured without extending the supporting part outside the vibration body, which can further reduce the size of the vibrating element.

### Application Example 5

In the vibration element according to the application example described above, the supporting part may include a connection beam that connects the joining parts provided respectively on at least two of the side surfaces exposed by the cut section, and a supporting beam that extends from the fixing part and connects to the connection beam.

According to the present application example, the supporting part is formed from a connection beam that connects the joining parts provided respectively on at least two of the side surfaces exposed by one of the cut sections, and a supporting beam that extends from the fixing part and connects to the connection beam. Due to this structure, much of the energy of vibration leakage that may transmit from the joining part of the vibration body to the fixing part can be absorbed as torsion of the connection beam. In particular, when the connection beam is connected to a portion of the node of vibration, vibration leakage can be reduced most.

### Application Example 6

In the vibration element according to the application example described above, the connection beam is connected with a plurality of the supporting beams.

According to the present example, the vibration body is configured to be connected with and supported by the plural supporting beams for each of the connection beams, such that the rigidity for supporting the vibration body increases. For example, in the manufacturing process of forming the vibration body that is isolated over the primary surface of the substrate, the sticking phenomenon in which the vibration body adheres to the primary surface of the substrate would be difficult to occur, even when the surface tension of etching liquid and cleaning liquid act between them. As a result, reduction of the yield due to sticking can be suppressed.

### Application Example 7

In the vibration element according to the application example described above, as the vibration body is viewed in a plan view, the vibration body may be in a rotationally symmetrical shape.

According to the present application example, the vibration body is formed in a rotationally symmetrical shape, such that the vibration body can be vibrated in a more balanced manner. As a result, a vibration element that exhibits more stabled vibration characteristics can be obtained.

### Application Example 8

In the application example described above, the joining part may preferably be formed at a portion that includes a node of vibration formed between the peripheral portion and the central portion as the peripheral portion of the vibration body and the central portion of the vibration body vibrate in opposite phase in the thickness direction of the vibration body.

According to the present application example, when the peripheral portion and the central portion of the vibration body vibrate in opposite phase in the thickness direction of the vibration body, a node of vibration is formed between the peripheral portion and the central portion. The joining part is formed at a portion that includes the node of vibration, such that a vibration element of free-free beam type is formed, and therefore a vibration element with high vibration efficiency can be composed. Also, as the supporting part is joined at the node of vibration, a vibration element with little vibration leakage can be composed.

### Application Example 9

In the vibration element according to the application example described above, the vibration body may be an upper electrode, and a first lower electrode may be provided between the substrate and an area surrounded by the node of vibration of the vibration body and the connection beam.

According to the present application example, the vibration element is formed from the upper electrode and the first lower electrode disposed in a position that overlaps the central portion (an area surrounded by the node of vibration and the connection beam) of the upper electrode, and may be composed as an electrostatic oscillator that vibrates with the peripheral portion and the central portion (a central portion on the inner side of the joining part) of the vibration body (the upper electrode) as anti-nodes of vibration.

### Application Example 10

In the vibration element according to the application example described above, the vibration body may be an upper electrode, and a second lower electrode may be provided between the substrate and an area outside the area surrounded by the node of vibration of the vibration body and the connection beam.

According to the present application example, the vibration element is formed from the upper electrode and the second lower electrode disposed in a position that overlaps the peripheral portion (an area outside an area surrounded by the node of vibration and the connection beam) of the upper electrode, and may be composed as an electrostatic oscillator that vibrates with the peripheral portion and the central portion (a central portion on the inner side of the joining part) of the vibration body (the upper electrode) as anti-nodes of vibration.

### Application Example 11

In the vibration element according to the application example described above, the vibration body may be an upper electrode, and the vibration element may include a first lower electrode provided between the substrate and an area surrounded by the node of vibration of the vibration body and the connection beam, and a second lower electrode provided between the substrate and an area outside the area surrounded by the node of vibration of the vibration body and the connection beam.

According to the present application example, the vibration element is formed from the upper electrode, the first lower electrode disposed in a position that overlaps the central portion (an area surrounded by the node of vibration and the connection beam) of the upper electrode, and the second lower electrode disposed in a position that overlaps the peripheral portion (an area outside the area surrounded by the node of vibration and the connection beam) of the upper electrode, and may be composed as an electrostatic oscillator that vibrates with the peripheral portion and the central portion (a central portion on the inner side of the joining part) of the vibration body (the upper electrode) as anti-nodes of vibration.

### Application Example 12

In the vibration element according to the application example described above, the vibration body may vibrate by a first AC voltage impressed between the upper electrode and the first lower electrode and a second AC voltage impressed in opposite phase of the first AC voltage between the upper electrode and the second lower electrode.

According to the present application example, at the first lower electrode arranged at a position overlapping the central portion of the upper electrode and the second lower electrode arranged at a position overlapping the peripheral area of the upper electrode, AC voltages in opposite phase are impressed between them and the upper electrode, such that a vibration element with higher vibration energy can be composed.

### Application Example 13

An electronic device in accordance with an application example may be equipped with the vibration element according to the application example described above.

According to the present application example, a vibration element that is further miniaturized without deteriorating high performance, whose manufacturing yield is stabilized at high level, is used in the electronic device. Accordingly, an electronic device with higher performance at lower cost can be provided.

### BRIEF DESCRIPTION OF THE DRAWINGS

FIG. 1A is a plan view of a MEMS vibration element, which is a vibration element in accordance with Embodiment 1, FIG. 1B is a cross-sectional view taken along a line A-A of FIG. 1A, and FIG. 1C is a cross-sectional view taken along a line B-B of FIG. 1A.

FIGS. 2A-2F are conceptual illustration of main vibration modes of a vibration element having a moveable electrode in a circular disc shape.

FIG. 3 is a plan view of a MEMS vibration element, which is a vibration element in accordance with Embodiment 2.

FIG. 4A is a perspective view showing the structure of a personal mobile computer, which is an example of an electronic device, and FIG. 4B is a perspective view showing the structure of a cellular phone, which is another example of an electronic device.

FIG. 5 is a perspective view showing the structure of a digital camera, which is an example of an electronic device.

FIGS. 6A-6C are plan views showing exemplary variations of a lower electrode, in MEMS vibration elements in accordance with Modified Example 1.

FIG. 7 is a plan view showing one of exemplary variations of a supporting part, in a MEMS vibration element in accordance with Modified Example 2.

FIGS. 8A-8C are plan views showing exemplary variations of an upper electrode (a vibration body) and a supporting part, in a MEMS vibration element in accordance with Modified Example 3.

FIG. 9 is a plan view showing one of exemplary variations of an upper electrode, in a MEMS vibration element in accordance with Modified Example 4.

### DESCRIPTION OF EXEMPLARY EMBODIMENTS

Concrete exemplary embodiments of the invention are described below with reference to the accompanying drawings. Note that the embodiments described herein are examples of the invention, and do not limit the invention. Also note that elements shown in the accompanying drawings may be in scales different from the actual scale, for the sake of easy understanding of the description.

### Embodiment 1

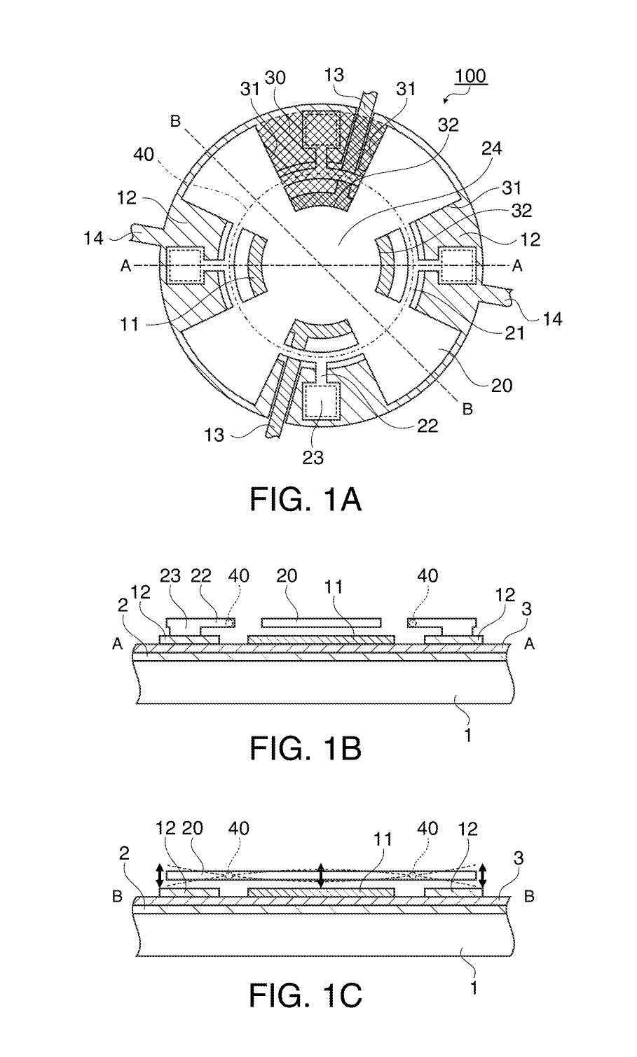

First, a MEMS vibration element 100, which is a vibration element in accordance with Embodiment 1, is described. FIG. 1A is a plan view of the MEMS vibration element 100, FIG. 1B is a cross-sectional view taken along a line A-A of FIG. 1A, and FIG. 1C is a cross-sectional view taken along a line B-B of FIG. 1A. The MEMS vibration element 100 is a MEMS vibration element having a substrate with a moveable upper electrode (a vibration body) that is formed, being isolated from the substrate, by etching a sacrificial layer laminated on the principal surface of the substrate. Note that the sacrificial layer is a layer that is temporarily formed with an oxide layer or the like, and is removed by etching after forming necessary layers above, below or around the sacrificial layer. By removing the sacrificial layer, a necessary gap or cavity is formed in each layer above, below or around the necessary layers, or a isolated structure required is formed.

The MEMS vibration element 100 is formed from a substrate 1, a first lower electrode 11, a second lower electrode 12, an upper electrode 20 as a vibration body, supporting parts comprised of connection beams 21 and supporting beams 22, and fixing parts 23. The upper electrode 20 is a movable electrode (a vibration body) in a circular disc shape having cut sections, and is supported by the supporting parts that extend from the respective fixing parts 23, isolated from the substrate 1.

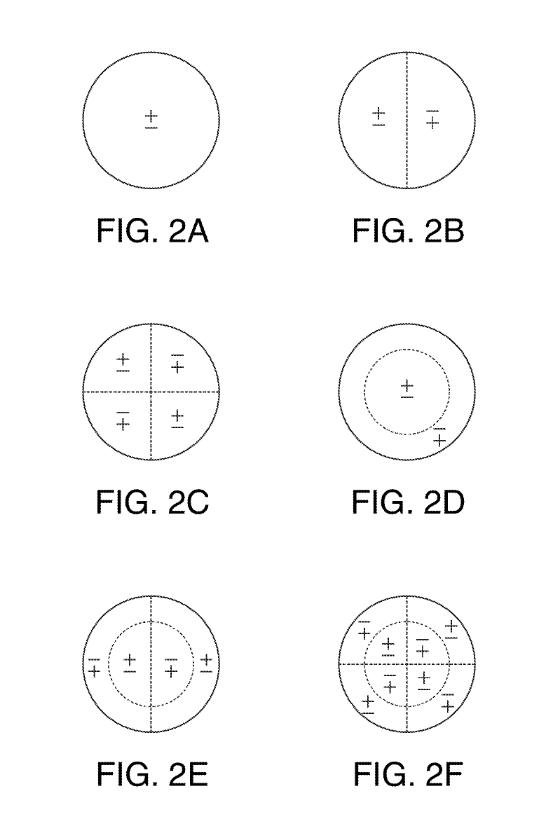

FIGS. 2A-2F illustrate main vibration modes of the vibration element having the moveable electrode in a circular disc shape. In the figures, a broken line indicates a node of vibration, + and − signs indicate portions that vibrate in an upward or a downward direction (in the thickness direction of the substrate 1) as anti-nodes, including their relation in phase. For example, when the + sign indicates a movement in an upward direction, an adjacent area indicated by the − sign moves in a downward direction with a node of vibration as the boundary.

The MEMS vibration element 100 is a vibration element with the vibration mode indicated in FIG. 2D, and realizes this vibration mode according to the arrangement of the first lower electrode 11 and the second lower electrode 12, and the AC voltage impressed between these electrodes and the upper electrode 20.

Referring to FIGS. 1A through 1C, the structure of the MEMS vibration element 100 is concretely described. The MEMS vibration element 100 is a vibration element in which a peripheral portion of the upper electrode 20 and a central portion of the upper electrode 20 vibrate as anti-nodes of vibration in up and down directions in opposite phase, and the node of vibration is formed as a node of vibration 40 in a ring shape between the peripheral portion and the central portion.

As a preferred example, the substrate 1 may be formed using a silicon wafer, without any particular limitation thereto, and may be formed from a semiconductor substrate of a different type or a glass substrate. The first lower electrode 11, the second lower electrode 12, the upper electrode 20, the connection beams 21, the supporting beams 22 and the fixing parts 23 are formed above a first oxide film 2 and a nitride film 3 formed on a principal surface of the substrate 1. Note here that the present embodiment is described with the direction in which the first oxide film 2 and the nitride film 3 are laminated on the principal surface of the substrate 1 in this order, in the thickness direction of the substrate 1, as the upward direction.

The first lower electrode 11 and the second lower electrode 12 can be formed by patterning a lower conductive layer laminated over the nitride film 3 by photolithography. The first lower electrode 11 is formed in an area on the principal surface of the substrate 1 (above the nitride film 3) that is included in a region between the substrate 1 and an area surrounded by the node of vibration 40 of the upper electrode 20 and the connection beam 21. The second lower electrode 12 is formed in an area on the principal surface of the substrate 1 (above the nitride film 3) that is included in a region between the substrate 1 and an area outside the area surrounded by the node of vibration 40 of the upper electrode 20 and the connection beam 21.

The upper electrode 20 is formed in a circular plate like shape having four cut sections 30, and is supported, being isolated from the substrate 1, by supporting beams 22 and connection beams 21 extending respectively from four fixing parts 23 arranged in the areas of the cut sections 30. The fixing parts 23 are disposed in the areas of the cut sections 30, on the outer side of the node of vibration 40 (on the side of the peripheral portion).

As shown in FIG. 1A, the cut section 30 (one of the four cut sections is shown with crosshatching) is a cut formed along the radial direction of the upper electrode 20, extending from the peripheral portion of the upper electrode 20 toward the central portion of the upper electrode 20, passing through the node of vibration 40. An area extending from the center of the upper electrode 20 left inside the cut sections 30 up to the cut sections 30 forms the central portion 24 that forms an anti-node of vibration of the central portion that vibrates in opposite phase to the peripheral portion of the upper electrode 20.

By the cut sections 30, side surfaces 31 defining side surface portions oriented from the peripheral portion toward the central portion 24 of the upper electrode 20, and side surfaces 32 facing the peripheral portion from the central portion 24 are formed in the upper electrode 20. The side surfaces 31 include the node of vibration 40, and are provided with joining parts to be joined to the connection beams 21 in an area including the node of vibration 40. In other words, the fixing parts 23 support the node of vibration 40 through the supporting beams 22 and the connection beams 21.

Each of the connection beams 21 is a beam that connects sections of the node of vibration 40 that is included in each of the two side surfaces 31 exposed by each of the cut sections 30, and is formed in a manner to extend along the node of vibration 40 that extends in a circle. Note that the connection beam 21 may preferably be formed as thin as possible in order to reduce vibration leakage from the joining part to the fixing part 23. The supporting beam 22 extends from the fixing part 23, reaching the central area of the connection beam 21, and supports the connection beam 21.

The upper electrode 20 is formed in a rotationally symmetrical shape, as viewed in a plan view. More specifically, the four cut sections 30 are formed (in other words, removed from the upper electrode 20) in the same size and the same shape, respectively, and are arranged at mutually equal intervals. Note that the number of the cut sections 30 and the number of the connection beams 21, the supporting beams 22 and the fixing parts 23 associated therewith are not limited to four. They can be increased within the range that can sufficiently control sticking, but the shape of the upper electrode 20 may preferably be formed in a rotationally symmetrical shape, as viewed in a plan view.

The upper electrode 20, the fixing parts 23, and the supporting beams 22 and the connection beams 21 extending from the respective fixing parts 23 are formed by patterning an upper conductive layer laminated over the lower conductive layer (used for forming the first lower electrode 11 and the second lower electrode 12) through a sacrificial layer by photolithography. In other words, the patterning is conducted to form the cut sections 30, and form the upper electrode 20, the fixing parts 23, the supporting beams 22 and the connection beams 21 in one piece, such that the connection beams 21 connect to the joining parts at the side surfaces 31 to support, together with the supporting beams 22, the upper electrode 20.

The cut section 30 is provided with a width (i.e., a distance between the opposing side surfaces 31 along the radial direction exposed by the cut section 30) that can secure a sufficient length for the connection beam 21. More specifically, because the connection beam 21 connects to the joining part that includes the node of vibration 40, the connection beam 21 is subject to stress generated by movements about the axis of the node of vibration 40, which is caused by the vibration of the upper electrode 20. The stress acts with the supporting beam 22 that extends from the fixing part 23 as torsional stress to the connection beam 21. When the length of the connection beam 21 is short, the torsional stress is not absorbed, and acts in a direction against the vibration. Therefore, the connection beam 21 needs to be formed as thin as possible, and have a sufficient length by which necessary vibration can be obtained.

Note that bottom parts of the fixing parts 23 are fixed to the lower conductive layer (the second lower electrode 12). In other words, no sacrificial layer is laminated in an area at the bottom parts of the fixing parts 23, and the fixing parts are laminated directly on the lower conductive layer. Accordingly, even when the sacrificial layer is removed by etching, the fixing parts 23 are fixed to the lower conductive layer. Therefore, the upper electrode 20 is electrically connected to the second lower electrodes 12 through the connection beams 21, the supporting beams 22 and the fixing parts 23. Further, the upper electrode 20 is arranged isolated from the substrate 1, as the sacrificial layer is removed by etching.

The lower conductive layer and the upper conductive layer may preferably be formed from conductive polysilicon, for example, without any particular limitation thereto, and may also use any one of other types of conductive layer that are used for semiconductor circuits. For achieving a conductivity required as an electrostatic vibration element or for the upper conductive layer, the conductive layer needs to be equipped with sufficient rigidity (stiffness) required as the vibration element.

The upper electrode 20, the second lower electrode 12 and the first lower electrode 11 are connected to an external circuit via electrical wiring to be connected from around the MEMS vibration element 100. The upper electrode 20 and the second lower electrode 12 are connected to an external circuit (not shown) through wiring 14 to be connected with the second lower electrode 12 from around the MEMS vibration element 100. The first lower electrode 11 is connected to an external circuit through wiring 13 insulated from the second lower electrode 12, from around the MEMS vibration element 100 in any of the areas of the four cut sections 30. In the example shown in FIG. 1A, the pattern of the second lower electrode 12 is isolated at two areas through which the wiring 13 passes, thereby forming two land patterns. Each of the land patterns is connected with the external circuit by the wiring 14.

With the structure described above, the MEMS vibration element 100 is composed as an electrostatic vibration element, and the peripheral portion and the central portion 24 of the upper electrode 20 vibrate as anti-nodes of vibration in opposite phase by an AC voltage impressed from the external circuit between the upper electrode 20 and the first lower electrode 11.

As described above, according to the MEMS vibration element 100, which is a vibration element in accordance with the present embodiment, the following effect can be obtained.

The upper electrode 20 has joining parts on the side surfaces 31 exposed by the cut sections 30 formed in an orientation from the peripheral portion toward the central portion 24 of the upper electrode 20, and the joining parts are supported by the supporting beams 22 and the connection beams 21, isolated from the substrate 1. In other words, the supporting parts composed of the supporting beams 22 and the connection beams 21 connect to the joining parts located on the inner side of the peripheral portion of the upper electrode 20 to thereby support the upper electrode 20, such that a vibration element that vibrates with the peripheral portion and the central portion 24 of the upper electrode 20 as anti-nodes of vibration can be composed.

In the case of the prior art vibration element of free-free beam type, for example, the supporting parts are connected to nodes of vibration located on the side surfaces of the vibrating plate, such that the number of supporting parts cannot be increased greater than the number of nodes of vibration on the side surfaces. Moreover, the supporting parts need to be extended in a direction away from the side surfaces of the vibration plate, such that the area occupied by the vibrating element including the supporting parts unavoidably becomes greater than that of the vibrating plate.

In contrast, according to the MEMS vibration element 100, which is a vibration element in accordance with the present embodiment, the upper electrode 20 is provided with the cut sections 30 extending from the peripheral portion toward the node of vibration 40 located on the inner side of the upper electrode 20, and the joining parts connecting to the supporting parts are formed on the side surfaces 31 exposed by the cut sections 30, such that the number of supporting parts may be increased without any limitation, by providing a necessary number of cuts. As a result, the rigidity for supporting the upper electrode 20 increases. Accordingly, for example, in the manufacturing process of forming the upper electrode 20 that is isolated over the primary surface of the substrate 1, the sticking phenomenon in which the upper electrode 20 adheres to the primary surface of the substrate 1 (to the first lower electrode 11, the second lower electrode 12 or the nitride film 3) would be difficult to occur, even when the surface tension of etching liquid and cleaning liquid act between them. As a result, reduction of yield due to sticking can be suppressed.

Furthermore, the supporting parts and the fixing parts 23 are provided in empty area created by the cut sections 30, such that the vibrating element can be composed without extending the supporting parts outside the upper electrode 20. Alternatively, the extension length of the supporting parts can be made shorter, which can further reduce the size of the vibrating element.

Moreover, by forming the upper electrode 20 from a circular plate body having the cut sections 30, a vibration element that vibrates with the peripheral portion and the central portion of the upper electrode 20 as anti-nodes can be composed. As the upper electrode 20 is composed in a circular shape, the position of the vibration node 40 and vibration characteristic can be readily designed.

Also, as the fixing parts 23 are provided in area that overlaps the cut sections 30, in other words, empty area created by the cut sections 30, the vibration element can be structured without extending the supporting parts outside the upper electrode 20, which can further reduce the size of the vibrating element.

Also, the supporting parts are each composed of the connection beam 21 that connects the joining parts located on the inner sides 31 exposed by each of the cut sections 30, and the supporting beam 22 extending from the fixing part 23 and connecting to the connection beam 21. Due to this structure, much of the energy of vibration leakage that may transmit from the joining part of the upper electrode 20 to the fixing part 23 can be absorbed as torsion of the connection beam 21.

Also, as the upper electrode 20 is formed in a rotationally symmetrical shape, the upper electrode 20 can be vibrated in a more balanced manner. As a result, a vibration element that has fewer vibration leakage and exhibits more stabilized vibration characteristics can be obtained.

Furthermore, the upper electrode 20 vibrates with the peripheral portion and the central portion 24 of the upper electrode 20 as anti-nodes of vibration in opposite phase in the thickness direction, the node of vibration 40 is formed between the peripheral portion and the central portion 24. As the joining parts are formed at portions including the node of vibration 40, a vibration element of free-free beam type is composed, and therefore a vibration element with high vibration efficiency can be composed. Also, as the supporting parts are connected to the node of vibration 40, a vibration element with little vibration leakage can be composed.

### Embodiment 2

Next, a MEMS vibration element 101, which is a vibration element in accordance with Embodiment 2, is described. Note that the same components as those of the embodiment described above shall be appended with the same reference numbers, and their description will not be duplicated.

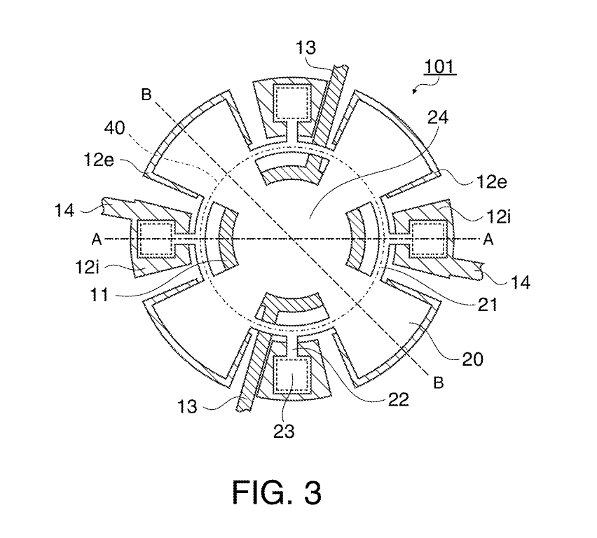

FIG. 3 is a plan view of the MEMS vibration element 101. The MEMS vibration element 101 includes a substrate 1, a first lower electrode 11, a second lower electrode 12e, an upper electrode 20 as a vibration body, supporting parts composed of connection beams 21 and supporting beams 22, fixing parts 23, and fixing bases 12i.

In Embodiment 1 (the MEMS vibration element 100), as shown in FIG. 1A, it is described that the upper electrode 20 is electrically connected to the second lower electrode 12 through the connection beams 21, the supporting beams 22 and the fixing parts 23. In accordance with an aspect of the present embodiment, the portion composing the second lower electrode 12 is divided into second lower electrodes 12e and fixing bases 12i. The MEMS vibration element 101 is generally the same as the MEMS vibration element 100 except the above-described aspect and wiring connection to the second lower electrodes 12e and the fixing bases 12i from an external circuit.

In the MEMS vibration element 101, an area corresponding to the area where the second lower electrode 12 and the cut section 30 overlap each other in the MEMS vibration element 100, as seen in a plan view, is divided as the fixing base 12i. More specifically, when the lower conductive layer is patterned by photolithography, the patterning is conducted in a manner that the fixing base 12i becomes isolated as a land, and is electrically insulated from the second lower electrode 12e.

Also, bottom parts of the fixing parts 23 are fixed to the fixing bases 12i of the lower conductive layer. In other words, the upper electrode 20 formed in one piece with the fixing parts 23 is electrically insulated from the second lower electrode 12e. Also, the second lower electrode 12e, which is insulated from the fixing bases 12i in the areas of the four cut sections 30, is electrically divided into four electrodes.

The upper electrode 20 is connected with an external circuit through wiring to be connected from around the MEMS vibration element 101 to the fixing bases 12i.

The four second lower electrodes 12e are connected with an external circuit through wiring to be connected from around the MEMS vibration element 101, or wiring penetrated through the nitride film 3 immediately below each of the second lower electrodes 12e (illustration omitted).

With the structure described above, the MEMS vibration element 101 is composed as an electrostatic vibration element, and the peripheral portion and the central portion 24 of the upper electrode 20 can be vibrated as anti-nodes of vibration in opposite phase by an AC voltage impressed between the upper electrode 20 and the first lower electrode 11, and an AC voltage impressed between the upper electrode 20 and the second lower electrode 12e in opposite phase to the aforementioned AC voltage.

According to the MEMS vibration element 101 which is a vibration element in accordance with the present embodiment, at the first lower electrode 11 arranged at a position overlapping the central portion 24 of the upper electrode 20 and the second lower electrode 12e arranged at a position overlapping the peripheral area of the upper electrode 20, AC voltages in opposite phase are impressed between them and the upper electrode 20, such that a vibration element with higher vibration energy can be composed.

### Electronic Device

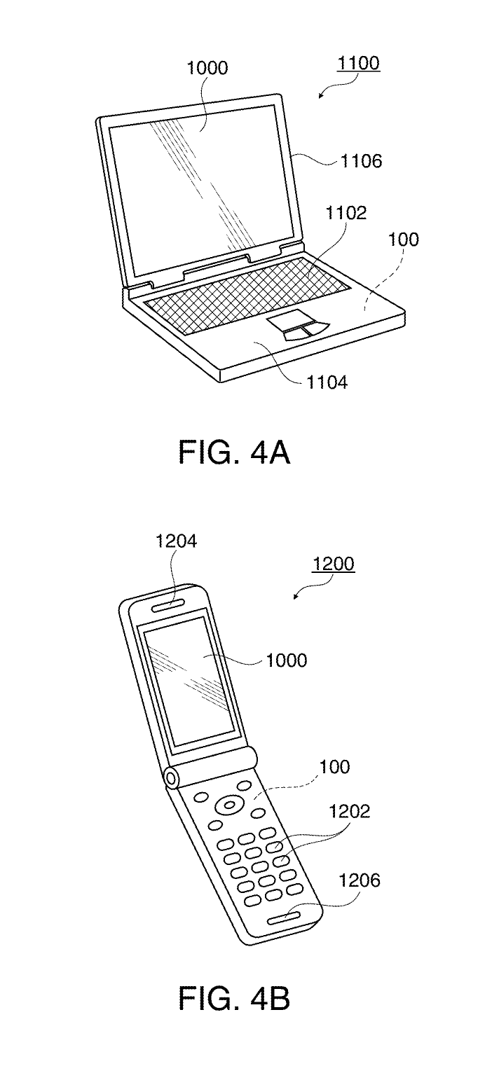

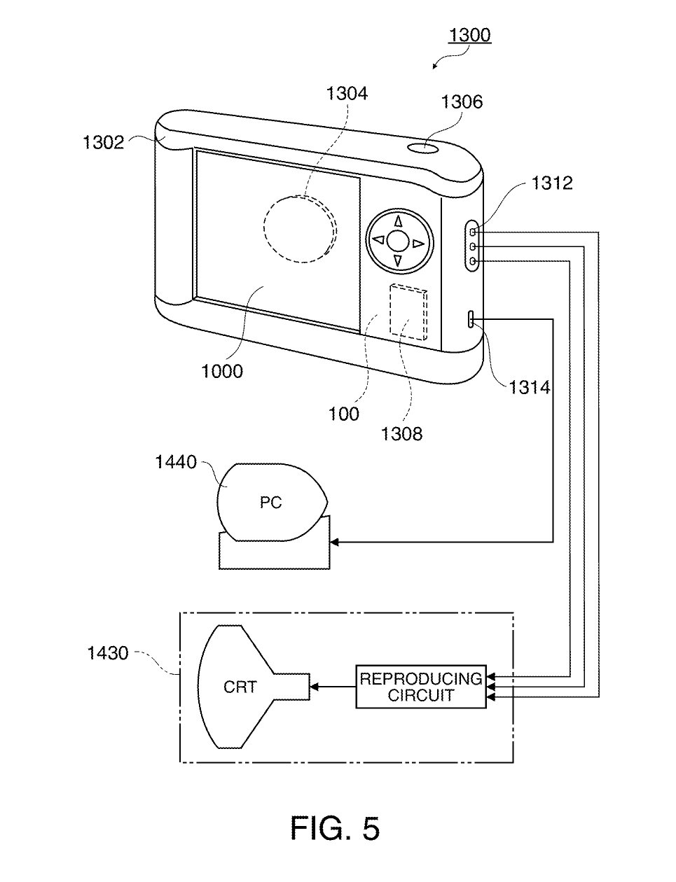

Electronic devices that use a MEMS vibration element 100 as an electronic component in accordance with an embodiment of the invention are described with reference to FIGS. 4A and 4B and FIG. 5.

FIG. 4A is a perspective view schematically showing the structure of a personal mobile (or notepad) computer, which is an electronic device equipped with the electronic component in accordance with an embodiment of the invention. In this figure, a personal computer 1100 is configured with a main body 1104 provided with a keyboard 1102 and a display unit 1106 provided with a display 1000. The display unit 1106 is rotatably supported by the main body 1104 through a hinge structure. The MEMS vibration element 100 as an electronic component that functions as, for example, a filter, a resonator, a reference clock or the like is built in the personal computer 1100.

FIG. 4B is a perspective view schematically showing the structure of a mobile phone (including a personal handy-phone system (PHS)), which is an electronic device equipped with an electronic component in accordance with an embodiment of the invention. The mobile phone 1200 shown in the figure includes plural operation buttons 1202, an earpiece 1204, and a mouthpiece 1206, and a display 1000 that is arranged between the operation buttons 1202 and the earpiece 1204. A MEMS vibration element 100 as an electronic component (a timing device) that functions as, for example, a filter, a resonator, an angular velocity sensor or the like is built in the mobile phone 1200.

FIG. 5 is a perspective view schematically showing the structure of a digital camera (e.g., a digital still camera, etc.), which is an electronic device equipped with the electronic component in accordance with an embodiment of the invention. In this drawing, interfacing with external devices is simply illustrated. With the digital camera 1300, an optical image of an object is photoelectrically converted by an imaging device such as a CCD (Charge Coupled Device) to generate an image pickup signal (or an image signal).

In the rear surface of a case (or a body) 1302 of the digital camera 1300, a display 1000 is provided to display an image based on the image pickup signal generated by the CCD, and the display 1000 may function as a viewfinder to display the object as an electronic image. In the front surface of the case 1302 (on the rear surface side in the figure), there is provided an optical pickup unit 1304 including an optical lens (an imaging optical system), a CCD and the like.

When the user of the digital camera 1300 presses a shutter button 1306 after confirming an object image displayed on the display 1000, an image pickup signal generated by the CCD at that moment is transferred to and then stored in a memory 1308.

Further, on the side surface of the case 1302 of the digital camera 1300, a video signal output terminal 1312 and an input-output terminal for data communication 1314 are provided. As illustrated, when necessary, a television monitor 1430 and a personal computer 1440 may be connected to the video signal output terminal 1312 and the input-output terminal for data communication 1314, respectively. Further, an image pickup signal stored in the memory 1308 may be output to the television monitor 1430 or the personal computer 1440 by a predetermined operation. A MEMS vibration element 100 as an electronic component that functions as, for example, a filter, a resonator, an angular velocity sensor or the like is built in the digital camera 1300.

As described above, by using a MEMS vibration element 100 which is smaller in size and provides stable manufacturing yield at high level as an electronic device, a smaller and more inexpensive electronic device can be provided.

In addition to the personal computer (or personal mobile computer), the mobile phone, and the digital camera described above with reference to FIG. 4A, FIG. 4B and FIG. 5, the MEMS vibration element 100, as an electronic component in accordance with an embodiment of the invention, is also applicable to other electronic apparatuses, such as, ink jet devices (for example, ink jet printers), personal laptop computers, television sets, video cameras, car navigation devices, pagers, electronic notepads (including those with communication function), electronic dictionaries, electronic calculators, electronic game consoles, workstations, videophones, security television monitors, electronic binoculars, POS terminals, medical equipment (e.g., an electronic thermometer, a sphygmomanometer, a blood glucose meter, an electrocardiograph monitor, ultrasonic diagnostic equipment, and an endoscope monitor), fish detectors, various measuring instruments, gages (e.g., gages for vehicles, aircraft, and boats and ships), flight simulators, and the like.

Note that the invention is not limited to the embodiments described above, and various changes and improvements can be made to the embodiments described above. Some modified examples are described below. Note that the same constituting elements as those of the embodiments described above will be appended with the same reference numbers, and their description will not be duplicated.

### Modified Example 1

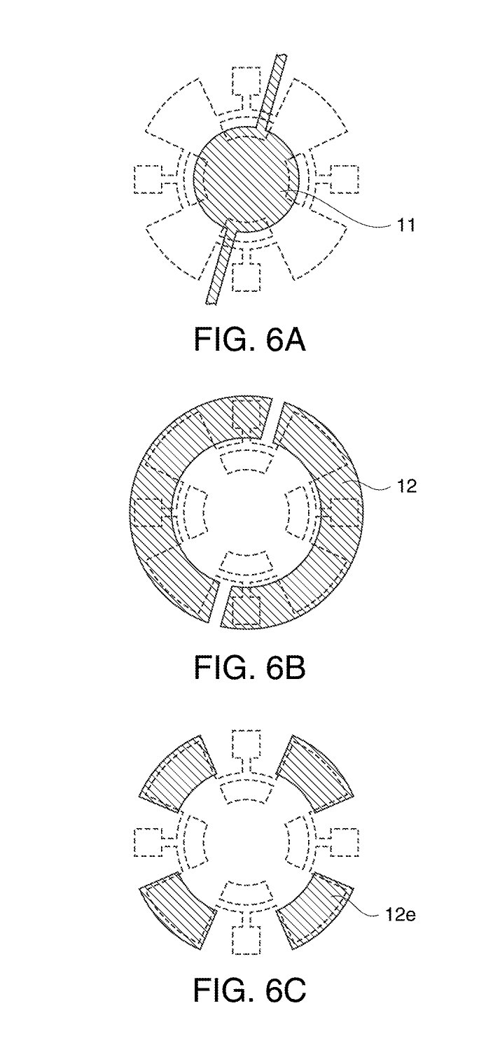

FIGS. 6A-6C are plan views showing examples of lower electrodes in various configurations, in MEMS vibration elements in accordance with Modified Example 1. In Embodiment 1, as shown in FIG. 1A, the lower electrode is described to have two electrodes, i.e., the first lower electrode 11 and the second lower electrode 12. However, without any limitation to such configuration, the lower electrode may be composed only with one of the lower electrodes.

In the modified example shown in FIG. 6A, the lower electrode is composed of only the first lower electrode 11. In the modified example shown in FIG. 6B, the lower electrode is composed of only the second lower electrodes 12. In the modified example shown in FIG. 6C, the lower electrode is composed of only second lower electrodes 12e.

According to the compositions described above, an electrostatic vibration element with a vibration mode similar to that of the embodiments described above can be composed, though they have different vibration energy. According to the composition having only one of the lower electrodes as in the present modified example, wiring to the lower electrode can be more readily performed, without giving any consideration to insulation at proximate or traversing wirings to each of the first lower electrode 11 and the second lower electrodes 12.

### Modified Example 2

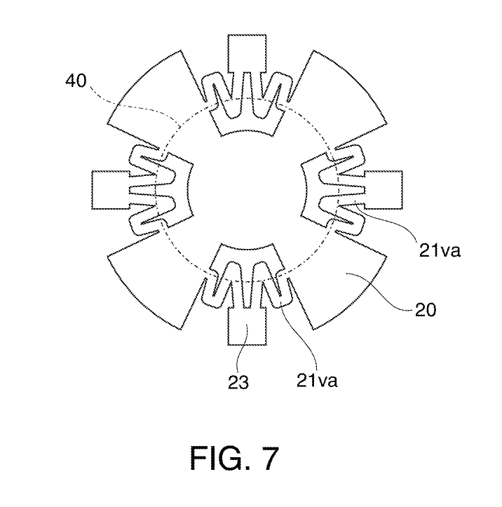

FIG. 7 is a plan view schematically showing an exemplary variation of the supporting parts in an MEMS vibration element in accordance with Modified Example 2. In the embodiment 1, it is described that the connection beam 21 is a beam that connects portions of the node of vibration 40 included in the two side surfaces 31 exposed by each one of the cut sections 30, and the connection beams 21 are formed in a manner to extend along the node of vibration that extends in a ring shape, as shown in FIG. 1A. Also, the supporting beam 22 extends from the fixing part 23, respectively, and connects to the central area of the connection beam 21, thereby supporting the connection beam 21. In contrast, the present modified example, as shown in FIG. 7, is equipped with connection and supporting beams 21va having bent sections, as supporting parts that connect to the joining parts of the side surfaces 31.

The connection and supporting beam 21va has the function of the connection beam 21 and the supporting beam 22, one end thereof connects to the joining part of the side surface 31 that includes the node of vibration 40, and the other end connects to the fixing part 23. The connection and supporting beam 21va extends through two bent sections between the joining part and the fixing part 23, by which vibration leakage from the upper electrode 20 to the fixing parts 23 is suppressed. Note that the number of bent sections of the connection and supporting beam 21va is not limited to two. The shape and the width (thickness) of the connection and supporting beam 21va may preferably be set within the range that allows the necessary and sufficient rigidity. More specifically, they may preferably be set within the range in which vibration leakage from the upper electrode 20 to the fixing parts 23 in vibration can be sufficiently suppressed, and the rigidity that can suppress sticking of the upper electrode 20 during the manufacturing process can be obtained.

By providing the connection and supporting beams 21va like the present modified example as supporting parts, the fixing parts 23 can be provided in empty area created by the cut sections 30, and therefore a vibration element can be composed without extending the supporting parts outside the upper electrode 20, such that the vibration element can be made much smaller in size.

### Modified Example 3

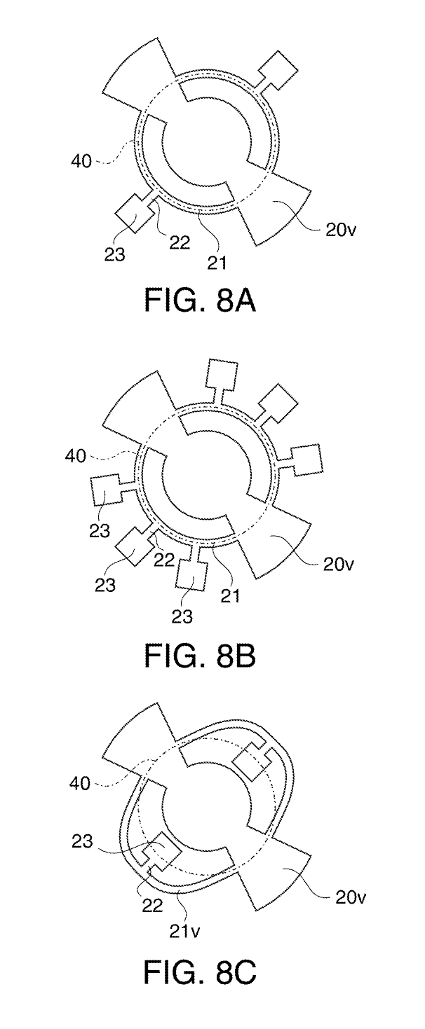

FIGS. 8A-8C are plan views showing exemplary variations of the upper electrode and the supporting parts of an MEMS vibration element in accordance with Modified Example 3. In Embodiment 1 described above, as shown in FIG. 1A, the upper electrode 20 is described as having a circular disc shape having four cut sections 30 extending from the peripheral portion toward the central portion. However, the upper electrode 20 is not limited to such a shape. As shown in FIGS. 8A-8C, the upper electrode 20v may be formed with two larger areas for cut sections.

In the modified example shown in FIG. 8A, the cut sections 30 are formed larger, and the number of the cut sections 30 is reduced to two, such that the connection beams 21 each have a greater length. According to this modified example, because the connection beams 21 are each formed to have a greater length, a vibration element with reduced vibration leakage can be obtained.

In the modified example shown in FIG. 8B, the number of the supporting beams 22 connecting to the connection beams 21 and the number of the fixing parts 23 are increased, compared to the modified example shown in FIG. 8A. According to the present modified example, the plural supporting beams 22 connect to each of the connection beams 21 to thereby support the upper electrode 20, such that the rigidity for supporting the upper electrode 20 increases. As a result, reduction of yield due to sticking during the manufacturing process can be suppressed.

In the modified example shown in FIG. 8C, the fixing parts 23 are disposed inside the connection beams 21, compared to the modified example shown in FIG. 8A. In the embodiment 1, the fixing parts 23 are described as being disposed in the areas outside the node of vibration 40 (on the side of the peripheral section), in the areas of the cut sections 30. However, the invention is not limited to such a configuration. As shown in FIG. 8C, the connection beams 21v may be formed to extend outside the node of vibration 40, whereby the fixing parts 23 can be disposed inside the connection beams 21v or inside the node of vibration 40 in Embodiment 1. According to the present modified example, the connection beams can be extended much longer in the same occupying area as a vibration element, a vibration element with much reduced vibration leakage can be composed.

### Modified Example 4

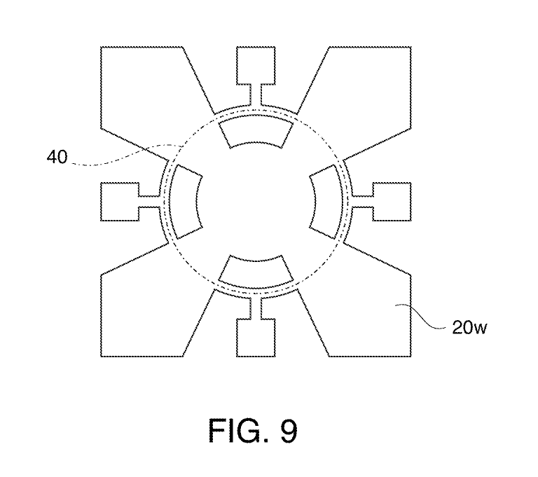

FIG. 9 is a plan view showing an exemplary variation of an upper electrode, which is a MEMS vibration element in accordance with Modified Example 4. FIG. 9 shows a modified example in which the upper electrode is not in a circular shape having cut sections, but is formed from a rectangular upper electrode 20w having cut sections. By forming the upper electrode 20w in a rectangular shape, the area outside of the node of vibration 40 of the upper electrode 20w can be made greater, compared to the case of Embodiment 1, such that the vibration efficiency achieved by AC voltage to be impressed between opposing second lower electrodes 12 can be improved. Note that the present modified example shows an upper electrode in a rectangular shape (a quadrilateral shape), but may be in any polygonal shape, such as, a triangular shape, a pentagonal shape, or the like, without any limitation to a rectangular shape.

The entire disclosure of Japanese Patent Application No. 2012-259442, filed Nov. 28, 2012 is expressly incorporated by reference herein.

What is claimed is:

1. A vibration element comprising:
a substrate;
a fixing part provided on a principal surface of the substrate;
a supporting part extending from the fixing part; and
a vibration body supported by the supporting part, isolated from the substrate,
the vibration body including a cut section extending from a peripheral portion of the vibration body toward a central portion of the vibration body, and a joining part provided at aside surface portion exposed by the cut section, and orienting in a direction from the peripheral portion toward the central portion, the joining part being connected to the supporting part.

2. A vibration element according to claim 1, wherein the vibration body has a circular disc shape having the cut section.

3. A vibration element according to claim 1, wherein the vibration body has a plurality of the cut sections.

4. A vibration element according to claim 1, wherein the fixing part is provided in an area that overlaps the cut section, as the substrate is viewed in a plan view.

5. A vibration element according to claim 1, wherein the supporting part includes a connection beam that connects the joining parts provided on at least two side surface portions exposed by the cut section, and a supporting beam extending from the fixing part and connecting to the connection beam.

6. A vibration element according to claim 5, wherein a plurality of the supporting beams connect to the connection beam.

7. A vibration element according to claim 1, wherein the vibration body is in a rotationally symmetrical shape, as the substrate is viewed in a plan view.

8. A vibration element according to claim 1, wherein the joining part is formed at a portion that includes a node of vibration formed between the peripheral portion and the central portion created as the peripheral portion of the vibration body and the central portion of the vibration body vibrate in opposite phase in a thickness direction of the vibration body.

9. A vibration element according to claim 8, wherein the vibration body is an upper electrode, and comprising a first lower electrode provided between the substrate and an area surrounded by the node of vibration of the vibration body and the connection beam.

10. A vibration element according to claim 8, wherein the vibration body is an upper electrode, and comprising a second lower electrode provided between the substrate and an area outside the area surrounded by the node of vibration of the vibration body and the connection beam.

11. A vibration element according to claim 8, wherein the vibration body is an upper electrode, and comprising a first lower electrode provided between the substrate and an area surrounded by the node of vibration of the vibration body and the connection beam, and a second lower electrode provided between the substrate and an area outside the area surrounded by the node of vibration of the vibration body and the connection beam.

12. A vibration element according to claim 11, wherein the vibration body vibrates by a first AC voltage impressed between the upper electrode and the first lower electrode and a second AC voltage impressed in opposite phase of the first AC voltage between the upper electrode and the second lower electrode.

13. An electronic device comprising the vibration element recited in claim 1.
